(19) United States
(12) Patent Application Publication
(10) Pub. No.: US 2007/0046397 A1
(43) Pub. Date: Mar. 1, 2007

(54) Nonlinear internal resonance based micromechanical resonators

(75) Inventors: Anil K. Bajaj, West Lafayette, IN (US); Ashwin Vyas, Lafayette, IN (US); Arvind Raman, W. Lafayette, IN (US); Dimitrios Peroulis, West Lafayette, IN (US)

Correspondence Address: BRINKS HOFER GILSON & LIONE, P.O. BOX 10395, CHICAGO, IL, 60610, US

(73) Assignee: Purdue Research Foundation, West Lafayette, IN (US)

(21) Appl. No.: 11/496,881

(22) Filed: Jul. 31, 2006

Related U.S. Application Data
(60) Provisional application No. 60/704,291, filed on Aug. 1, 2005.

(51) Int. Cl. H03H 9/00

(52) U.S. Cl. 333/186

(57) ABSTRACT

A micromechanical resonator having a structure defining a first mode and a second mode and permitting non-linear internal resonance between the first and second modes. The resonator may further include a first component embodying a first mode and a second component embodying a second mode such that the first and second modes are substantially completely non-linearly coupled with each other while the second component vibrates at a frequency approximately twice the at least one first natural resonance frequency.

### CROSS-REFERENCE TO RELATED APPLICATION

This patent application claims the benefit under 35 U.S.C. § 119(e) of U.S. provisional patent application Ser. No. 60/704,291, filed Aug. 1, 2005 and entitled NONLINEAR INTERNAL RESONANCE BASED MICROMECHANICAL RESONATORS, the entire contents of which are incorporated herein by reference.

### BACKGROUND

1. Field of the Invention

The invention relates generally to a micromechanical resonator. More specifically, the invention relates to a micromechanical resonator having nonlinear 1:2 internal resonance between any two linear modes of the mechanical resonator.

2. Related Technology

Micromechanical resonators constitute a key component of many microelectromechanical systems (MEMS) devices such as accelerometers, scanning force and atomic force microscopes (AFM), pressure and temperature sensors, and microvibromotors for controlled movements at small scale. Nonlinearities play important role in the dynamics of microresonators. For example, microstructures of microresonators typically experience geometric and inertial nonlinearities, which are caused by the structure of the microresonators, and actuation mechanism nonlinearities, which are caused by the actuation mechanism of the microresonators. As a more specific example, in the AFM cantilever probes resonant dynamics, van der Waals interactions are shown to lead to a softening nonlinear response while the short range repulsive forces lead to an overall hardening response. An inaccurate representation of nonlinearities can lead to an erroneous prediction of the frequency response and potentially failure of design based on the erroneous simulations.

Radio frequency (RF) filters are commonly used for various applications, such as wireless applications and hand-held communicator devices. RF filters typically include a filter component that receives input signals and filters out all or substantially all signals having a frequency other than a desired frequency. Additionally, RF filters often include a mixing component that adjusts the output frequency after the filtering operation has occurred. RF filters are conventionally made using crystals, which are relatively bulky and which consume a relatively large amount of power.

It is therefore desirable to design a microresonator that permits the user to utilize nonlinearities in improving the microresonator performance. It is also therefore desirable to provide a microresonator based RF filter having a reduced size and reduced power consumption while being capable of simultaneously filtering and mixing incoming signals.

### SUMMARY

In overcoming the limitations and drawbacks of the prior art, the present invention provides a micromechanical resonator having a structure defining a first (lower) mode and a second (higher) mode and permitting non-linear 1:2 internal resonance between the two designated distinct modes.

In another aspect of the present invention, a micromechanical resonator is provided, including a structural configuration having a first component embodying the first mode and a second component embodying the second mode. The first and second modes are substantially linearly decoupled from each other while the second mode vibrates at a frequency twice the natural frequency of the first mode.

In yet another aspect of the present invention, a micromechanical resonator is provided, including a structure having a first component defining a first mode and a second component defining a second mode, and an actuator configured to resonantly excite the second component at a second natural frequency. The second component is positioned with respect to the first component such that resonant excitation of the second component at the second frequency induces resonant excitation of the first component at a first natural frequency.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 shows a plan view of a micromechanical resonator embodying the principles of the present invention;

FIG. 2 is a schematic representation of the structure shown in FIG. 1, showing deflecting components of the structure with respect to a coordinate system;

FIG. 3 is a graphical representation of natural frequencies of the micromechanical resonator shown in FIG. 1 as a function of the length ratio of the beam segments for a particular set of values.

FIG. 4(a) is a schematic representation of the structure shown in FIG. 1 where the first mode is activated;

FIG. 4(b) is a schematic representation similar to FIG. 4(a), where the second mode is activated;

FIG. 5(a) is a graphical representation of the displacement of the tip of the vertical beam of the T-beam structure shown in FIG. 1 as a function of the excitation frequency, where the first mode is in the primary resonance;

FIG. 5(b) is a graphical representation of the vertical displacement of the junction of the three beams of the T-beam structure shown in FIG. 1 as a function of the excitation frequency, where the first (lower frequency) mode is directly excited by external means and is in primary resonance;

FIG. 6(a) is a graphical representation similar to FIG. 5(a), where the second (higher frequency) mode is directly excited by external actuation and is in the primary resonance;

FIG. 6(b) is a graphical representation similar to FIG. 5(b), of the vertical displacement of the junction of the three beams of the T-beam structure when the second (higher frequency) mode is in primary resonance;

FIG. 7(a) is a graphical representation of the displacement of the upper tip of the vertical beam shown in FIG. 1 as a function of excitation frequency, where the first (lower frequency) mode is directly excited in primary resonance;

FIG. 7(b) is a graphical representation of the displacement similar to FIG. 7(a), when the second (higher frequency) mode is directly excited in primary resonance;

FIG. 8 is a plan view of a second embodiment of a micromechanical resonator embodying the principles of the present invention; and

FIG. 9 is a plan view of a third embodiment of a micromechanical resonator embodying the principles of the present invention.

### DETAILED DESCRIPTION

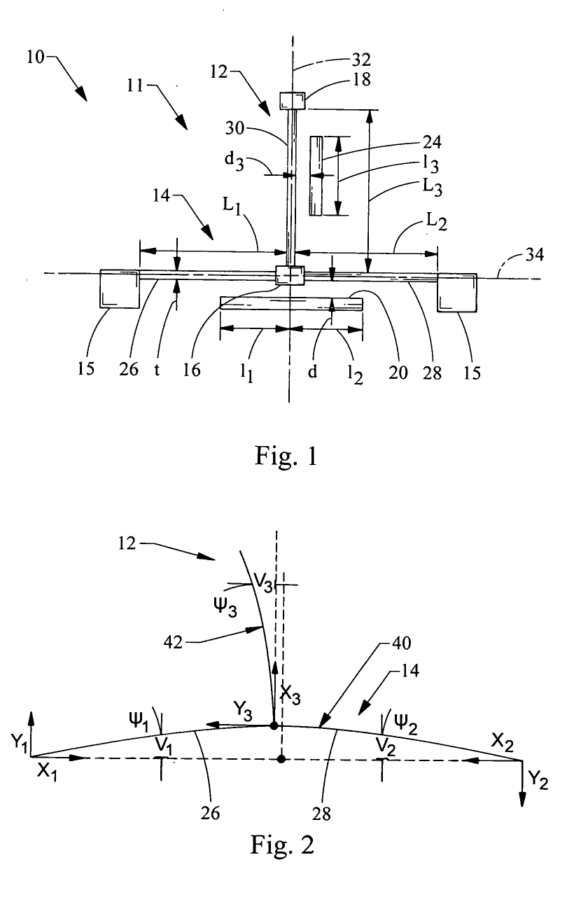

Referring now to the drawings, FIG. 1 is a schematic of a microresonator 10 according to a first embodiment of the present invention. The microstructure 10 generally includes a structure 11 defined by a first component 12 and a second component 14, a base 15 (or substrate) supporting the structure 11, a first mass 16 and a second mass 18 coupled with the structure 11, a first electrode 24 positioned adjacent to the first component 12, and a second electrode 20 positioned adjacent to the second component 12.

The second component 14 of the structure 11 includes a first horizontal beam 26 and a second horizontal beam 28, each having a first end connected to the base 15 and a second end connected to the first mass 16. Each of the horizontal beams 26, 28 may be connected to the base 15 that does not permit displacement or pivoting movement of the end of the beam 26, 28 at the base 15. Similarly, each horizontal beam 26, 28 may also be connected to the first mass 16 by a fixed connection. The horizontal beams 26, 28 shown in FIG. 1 both have equal or substantially equal specifications, such as length, width, thickness, diameter, and type of material, so the respective horizontal beams 26, 28 perform substantially identically when an external force is applied equally thereto.

The first component 12 of the structure 11 includes a vertical beam 30 coupled with the second component 14 of the structure 11 by the first mass 16. More specifically, one end of the vertical beam 30 may be connected to the midpoint of the first mass 16 so that the vertical beam 30 is centered along the length of the second component 14 and so that a vertical axis 32 of the first component 12 is generally perpendicular to a horizontal axis 34 of the second component 14. The other (free) end of the vertical beam 30 is connected to the second mass 18. The vertical beam 30 may be fixed to the first mass 16 by a fixed connection.

The second electrode 20 is an electrostatic electrode positioned adjacent to, and centered along the length of, the horizontal beams 26, 28. The second electrode 20 is connected to an electrical power supply that provides a bias voltage V_{b} and a harmonically fluctuating voltage V_{ac} sufficient, depending upon the quality factor determined by operating conditions, for selectively inducing resonance in the second component 14. For the structure with specific dimensions given below, and for a 1 um gap between the electrode 20 and the structure 26, 28 with quality factor Q=5000, Vproductthreshold=0.05Vˆ2, that is V_{b}=5V, and V_{AC}=0.01V.

Upon activation of the second electrode 20, an electro-static field is generated, thereby causing the second component 14 to deflect and define a second mode 40 (FIGS. 2 and 4(b)). As is known in the art, a mode is defined as the movement profile of an elastic body in which the body moves at a natural frequency. For example, the second (higher frequency) mode 40 defines a generally sinusoidal (in time) vertical deflection of the respective horizontal beams 26, 28 and displacement of the first mass 16 in response to the external force from the alternating current of the power supply. In this second mode, the vertical component 12 and the mass 18 also move axially along the axis 32 without flexing or deforming, as shown in FIG. 2. More specifically, the power supply causes the first mass 16 to move, and the horizontal beams 26, 28 to deflect, towards and away from the second electrode 20. Although for the specific design configuration of the present invention shown in FIG. 1, the second component 14 (see FIG. 1) embodies a single mode when the second electrode 20 is activated, the present invention may also be utilized in a microresonator in which a single physical component embodies two or more modes that are in 1:2 internal resonance.

When the input frequency of the power supply is not equal or approximately equal to a natural frequency of the higher mode of vibration (embodied in deflection of the second component 14), the amplitude of deflection of the second component 14 will be relatively low. Conversely, when the input frequency is equal or approximately equal to a natural resonance frequency of the second component 14, then the second component 14 will undergo resonance having a relatively high amplitude.

As a result of the deflection of the second component 14 in higher frequency mode of the microresonator, the first component 12 is likewise displaced along the vertical axis 32. More specifically, because each of the two horizontal beams 26, 28 deflects by an equal distance, the vertical beam 30 moves generally vertically along the vertical axis 32.

Similarly to the second electrode 20, the first electrode 24 is configured to generate an electrostatic field. This electrostatic field is able to detect disruptions in the electrostatic field caused by horizontal movement of the vertical beam 30. Thus, the first electrode 24 is able to detect deflection of the vertical beam 30 transverse to the vertical axis 32 (parallel to the horizontal axis 34). In an alternative configuration, the first electrode 24 operates to excite resonance in the lower frequency mode of the microresonator, which includes deflection of the first beam 12 while the second electrode 20 detects movement of the second beam 14. In another alternative design, a pair of electrodes is positioned adjacent to the second beam 30, one for exciting transverse (parallel to axis 34) movement of the second beam 30 and one for measuring the deflection of the second beam 30.

As mentioned above, when the second component 14 is not resonating, the first component 12 will undergo little or no deflection parallel to the horizontal axis 34. More specifically, when the second component 14 is not resonating, the first component 12 will remain generally straight and perpendicular to the first mass 16 so that the horizontal distance between the first beam 30 and the first electrode 24 remains relatively constant. As a result of the constant horizontal distance between the first beam 30 and the first electrode 24, the first electrode 24 will detect little or no change to the electrostatic field. Therefore, when the microresonator, and hence the second component 14, vibrates at a frequency other than a natural frequency, the second component 12 will not deflect horizontally. In other words, the higher frequency and the lower frequency natural modes, with specific examples shown in the form of modes 40, 42 in FIGS. 2, 4(a), and 4(b), are coupled with each other while the second component 14 vibrates at a frequency other than the higher (second) natural resonance frequency. This characteristic makes the structure 11 particularly useful as a filter because the first electrode 24 will detect little or no change in the electrostatic field adjacent to the first component 12 when the second component 14 is vibrating at a frequency other than the higher (second) natural frequency. Therefore, in this operational configuration, the microresonator 12 can be used to filter out all frequencies that are not very close to the higher natural frequencies of the microresonator, vibrating in second mode depicted in FIG. 4(b). In this higher mode, only the second component 14 flexes, as shown in FIG. 4(b).

Conversely, the first and second modes are substantially linearly decoupled from each other while the second mode vibrates at a frequency approximately twice the natural frequency of the first mode. In other words, due to 1:2 internal resonance which is discussed further below, when the microresonator is resonating in the higher frequency mode at the natural frequency that is approximately 2 times larger than the natural frequency of a lower frequency mode of the microresonator, the first component 12 will undergo horizontal deflection due to resonance of the lower frequency mode, as signified by the mode 42 in FIG. 4(a). More specifically, the second (higher) mode 40 (as embodied by the second component 14 and the first component 12) excites the first (lower) mode 42 (as embodied by the first component 12 and the second component 14) and causes the first component 12 to resonate along the horizontal axis in addition to vertical displacement along the vertical axis 32 caused by the second mode 40. As the first component 12 is deflected parallel to the horizontal axis 34, the first electrode 24 is able to detect deflection of the first component 12, thereby permitting the microresonator 10 to serve as a sensing device, or a signal processing filtering device.

The lower and higher frequency modes (the first and second modes 42, 40) are coupled with each other through a phenomenon known as nonlinear modal interaction. Non-linear modal interaction is defined as the phenomenon where one mode (in this case, the second mode 40) excites another mode (in this case, the first mode 42) through non-linear interactions within the structure. The structure 11 utilizes modal interactions in the two modes that arise due to inertial quadratic nonlinearities. Non-linear modal interaction in structure 11 occurs when the respective modes have natural frequencies having a ratio of 1:2. For example, if the second mode 40 (FIG. 4(b)) has a natural frequency of (f) and the first mode 42 (FIG. 4(a)) has a natural frequency of (f/2), then resonant excitation of the microresonator in its second mode 40 at frequency (f) will induce resonance of the first mode at a frequency of (f/2). Experimental results show that non-linear modal interaction is most effective when the ratio of natural frequencies is 1:2±0.5% so long as the Q factor is sufficiently high, as will be discussed in more detail below.

In order for 1:2 resonance to occur between the respective modes, the first and second components 12, 14 must have a particular length ratio and/or weight ratio. More specifically, the first and second components 12, 14 and the masses 16, 18 must have a suitable combination of structural characteristics for 1:2 resonance to occur. As a first example, the first mass 16 has a weight equal to the weight of the first component 12, the second mass 18 has a weight equal to the combined weight of the horizontal beams 26 and 28), and the first component 12 has a length approximately equal to 108% (±2%) of one of the horizontal beams 26, 28. In an alternative design, where no additional masses (masses 16 and 18) are present and the first and second components 12, 14 each have the same thickness and are made of the same material, the first component 12 has a length approximately equal to 133% (±2%) of one of the horizontal beams 26, 28.

The above scenario describes non-linear modal interaction when the higher (second) frequency mode 40 (signified by flexing of the component 14) is excited by an external force (the second electrode 20). However, non-linear modal interaction may also occur when the lower (first) frequency mode 42 (signified by flexing of both the components 12 and 14) is resonantly excited by an external force (such as the first electrode 24), thereby inducing response of the second mode 40. More particularly, if the first electrode 24 excites the first (lower frequency) mode 42 at a natural frequency that is ½ as large as a natural frequency of the second (higher frequency) mode 40, then the second mode 40 will be induced by the first mode 42.

In the above-described scenarios, non-linear modal interaction occurs between the first and second modes. In a real working model, due to variables such as damping or an imprecise 1:2 frequency ratio, the external force that excites one of the modes may have to have a threshold amplitude in order for non-linear modal interaction to occur. For example, structural damping inherent to the structure 11 or air damping caused by components moving through the air may reduce the effectiveness of the non-linear modal interaction, thereby reducing the overall Quality of the system. Similarly, if the 1:2 ratio between the natural frequencies of the two modes is not within an acceptable error range (such as ±0.5%) then the effectiveness of the non-linear modal interaction may also be reduced. However, these system imperfections may be overcome by increasing the amplitude of the input voltage to the electrode.

Referring to FIGS. 1 and 2, mathematical models representing the above-described micromechanical resonator will now be discussed in more detail. The two horizontal beams 26, 28 have lengths denoted by L1, and L2 and the vertical beam 30 has a length denoted by L3. The first and second masses 16, 18 are denoted by M_{c} and Mₜ respectively. Because the microresonator works on the principle of 1:2 internal resonance, the linear analysis for this T-beam structure is performed to determine the design conditions under which any two modes of the microresonator, and more specifically the first and second modes, are tuned for 1:2 modal interaction. In the present analysis, the rotary inertia terms for the beams are neglected as we are interested in only the lower modes (first two modes) of the beam structure. The motion is assumed to be in the horizontal plane (no gravity). The rotary inertia of the rigid masses are taken into account without including the finiteness (to simplify analysis) of these rigid masses. The second electrode 20 is assumed to span the bottom beam partially and, l₁ and l₂ denote the span of the second electrode 20 over the horizontal beams 26, 28. The second electrode 20 is located at a distance d from the horizontal beams 26 and 28. The sensor electrode 24 has a length denoted by l₃ and is located at a distance d₃ from the vertical beam 30. As mentioned above, these electrodes can be used for sensing the beam response or actuating the resonator depending upon the mode (shape) to be excited.

The coordinate systems and displacements of beam segments are shown in FIG. 2. Axial and transverse displacements of a beam element in three beams 26, 28, 30 are denoted by uᵢ and vᵢ, where i refers to the beam in consideration. The first horizontal beam 26 is beam 1, the second horizontal beam 28 is beam 2, and the vertical beam is beam 3. A Lagrangian description is used in modeling this T-beam structure and as a result these displacements are functions of undeformed arc length sᵢ. The displacements for the horizontal beams 26, 28 are with respect to the stationary substrate 15 and the displacements of the vertical beam 30 are measured with respect to the coordinate system located at the junction of the three beam segments 26, 28, 30. The rotation of a beam element is denoted by Ψᵢ(sᵢ,t). The shear deformation and warping are assumed to be negligible and thus, the rotations of elements are related to the beam displacements as follows:

$$sin {ψ}_{i} = \frac{\partial {v}_{i}}{\partial {s}_{i}} \qquad ( 1 )$$

The kinetic energy T and potential energy V (including the electrostatic potential) of the system are given by:

$$\begin{matrix}\begin{matrix}T = ( {\sum }_{i = 1}^{2} {\int }_{0}^{{L}_{i}} \frac{1}{2} {m}_{i} ( {\dot{u}}_{i}^{2} + {\dot{v}}_{i}^{2} ) ⅆ {s}_{i} ) + \\ {\int }_{0}^{{L}_{3}} \frac{1}{2} {{m}_{3} ( {\dot{u}}_{1} {\vert}_{{s}_{1} = {L}_{1}} - {\dot{v}}_{3} )}^{2} ⅆ {s}_{3} + \\ {\int }_{0}^{{L}_{3}} \frac{1}{2} {{m}_{3} ( {\dot{v}}_{1} {\vert}_{{s}_{1} = {L}_{1}} + {\dot{u}}_{3} )}^{2} ⅆ {s}_{3} + \\ \frac{1}{2} {M}_{c} ( {\dot{u}}_{1}^{2} {\vert}_{{s}_{1} = {L}_{1}} + {\dot{v}}_{1}^{2} {\vert}_{{s}_{1} + {L}_{1}} ) + \\ \frac{1}{2} {J}_{c} {\dot{ψ}}_{1}^{2 } {\vert}_{{s}_{1} = {L}_{1}} + \\ \frac{1}{2} {{M}_{t} ( {\dot{u}}_{1} {\vert}_{{s}_{1} = {L}_{1}} - {\dot{v}}_{3} {\vert}_{{s}_{3} = {L}_{3}} )}^{2} + \\ \frac{1}{2} {{M}_{t} ( {\dot{v}}_{1} {\vert}_{{s}_{1} = {L}_{1}} + {\dot{u}}_{3} {\vert}_{{s}_{3} = {L}_{3}} )}^{2} + \\ \frac{1}{2} {J}_{t} {\dot{ψ}}_{3}^{2} {\vert}_{{s}_{3} = {L}_{3}}\end{matrix} \} \\ and & ( 2 ) \\ \begin{matrix}V = {\sum }_{i = 1}^{3} {\int }_{0}^{{L}_{i}} \frac{1}{2} {( EI )}_{i} {( \frac{\partial {ψ}_{i}}{\partial {s}_{i}} )}^{2} ⅆ {s}_{i} + \\ {\sum }_{i = 1}^{2} {\int }_{0}^{{L}_{i}} \frac{1}{2} {( EA )}_{i} {e}_{i 0}^{2} ⅆ {s}_{i} - \\ ( {\int }_{{L}_{3} - {l}_{3}}^{{L}_{3}} \frac{1}{2} \frac{{ɛ}_{0} {ɛ}_{r} {b}_{3}}{d + {v}_{3}} {( {V}_{b} + V cos ( Ω t ) )}^{2} ⅆ {s}_{3} ) {M}_{1} - \\ ( {\sum }_{i = 1}^{2} {\int }_{{L}_{i} - {l}_{i}}^{{L}_{i}} \frac{1}{2} \frac{{ɛ}_{0} {ɛ}_{r} {b}_{i}}{d + {v}_{i}} {( {V}_{b} + V cos ( Ω t ) )}^{2} ⅆ {s}_{i} ) {M}_{2}\end{matrix} \} & ( 3 )\end{matrix}$$

where a dot denotes derivative with respect to time. The variables mᵢ and (EI)ᵢ denote the mass per unit length and flexural rigidity, respectively, for the ith beam. The rotary inertia of the masses M_{c} and Mₜ are J_{c} and Jₜ respectively. The variable bᵢ denotes the width of the ith beam. When the second electrode 20 is used for actuation, the variables M₁ and M₂ in expression (3) take on the values M₂=1 and M₁=0. When the first electrode 24 is used for actuation, then M₂=0 and M₁=1. The strain along neutral axis in ith beam is denoted by eᵢ₀. The strain eᵢ₀ can also be expressed in terms of axial and transverse displacements as follows:

$${e}_{i 0} = \sqrt{{( 1 + \frac{\partial {u}_{i}}{\partial {s}_{i}} )}^{2} + {( \frac{\partial {v}_{i}}{\partial {s}_{i}} )}^{2}} - 1 \qquad ( 4 )$$

The inextensibility assumption for vertical beam 30 results in the constraint e₃₀=0. In equation (3), the parameters ε₀ and εᵣ in the third term defining the electrostatic potential are permittivity of space (8.8504×10⁻¹² F/m) and the relative permittivity of dielectric between the gap (εᵣ=1 for air gap) respectively. The voltage applied between the second electrode 20 and the horizontal beams 26, 28 has a DC voltage part denoted by V_{b} and an AC part with frequency Ω and voltage amplitude V.

The augmented Lagrangian L accounting for the constraints is then as follows:

$$\begin{matrix}{L}_{avg} = T - V + \\ \frac{1}{2} {\int }_{0}^{{L}_{3}} {λ}_{1} ( {( 1 + \frac{\partial {u}_{3}}{\partial {s}_{3}} )}^{2} + {( \frac{\partial {v}_{3}}{\partial {s}_{3}} )}^{2} - 1 ) ⅆ {s}_{3}\end{matrix} \} \qquad ( 5 )$$

where λ₁ is the Lagrange multiplier imposing the inextensibility constraint.
Linear Analysis

First, a linear analysis of the structure will be discussed by evaluating the structure with small, finite amplitude oscillations. The transverse displacements vᵢ are scaled by a small dimensionless parameter ε. The axial displacements are assumed to be caused by transverse displacements and are of O(ε²). This essentially means that axial motion rigidity (EA)ᵢ is much larger than flexural rigidity (EI). These scalings are used to order nonlinear terms and only up to quadratic nonlinearities are retained in the present equations. As it will later turn out, the forcing will be scaled as O(ε²), and it will be seen that the effect of electrostatic actuation (including the non zero equilibrium position of the beam due to DC voltage) on linear natural frequencies will be of higher order. When retaining terms only up to the quadratic nonlinearities in the system (terms up to O(ε³)), the electrostatic actuation will only result in change in static equilibrium position.

The linear equations of motion are obtained by introducing these scalings in Lagrangian, Equation (5), then retaining terms up to the order of O(ε²) and using Hamilton's principle. The non-dimensionalized linear equations of motion turn out to be as follows:

$${{v}^{=}}_{i} + \frac{{α}_{i}}{{r}_{i} {v}_{i}^{4}} \frac{{\partial }^{4} {\overline{v}}_{i}}{\partial {\overline{s}}_{i}^{4}} = 0 , \qquad ( 6 )$$

where a dot now represents a derivative with respect to the non-dimensional time τ. These non-dimensional parameters are defined as follows:

$$\begin{matrix}{\overline{v}}_{i} = \frac{{v}_{i}}{L} , {\overline{s}}_{i} = \frac{{s}_{i}}{{L}_{i}} , {α}_{i} = \frac{{( EI )}_{i}}{EI} \\ {r}_{i} = \frac{{m}_{i}}{M} , {v}_{i} = \frac{{L}_{i}}{L} , τ = \sqrt{\frac{EI}{{ML}^{4}}} t .\end{matrix} \} \qquad ( 7 )$$

In defining these non-dimensional parameters of the system, M is a nominal mass per unit length, L is a nominal length, and EI is a nominal flexural rigidity. The arc length sᵢ of the ith beam is nondimensionalized using the length of the corresponding beam. Thus, the equations of motion are valid over the region O< s̅<1. Further, the transverse displacements are measured from the static equilibrium position of the beam which is changed due to electrostatic actuation. Thus, the formulation here assumes that the oscillations of the beam are about non-zero equilibrium position of the beam; however the non-zero equilibrium position effect on the natural frequencies are of higher order. The electrostatic potential terms are non-dimensionalized using the following scalings:

$$\begin{matrix}g = \frac{d}{L} , {\overline{l}}_{i} = \frac{{l}_{i}}{{L}_{i}} \\ {F}_{0} = ( \frac{{ɛ}_{0} {ɛ}_{r} {b}_{1}}{g} ( {V}_{b}^{2} + \frac{{V}^{2}}{2} ) ) / ( EI / L ) \\ {F}_{1} = ( \frac{{ɛ}_{0} {ɛ}_{r} {b}_{1}}{g} ( 2 {V}_{b} V ) ) / ( EI / L ) \\ {F}_{2} = ( \frac{{ɛ}_{0} {ɛ}_{r} {b}_{1}}{g} ( \frac{{V}^{2}}{2} ) ) / ( EI / L )\end{matrix} \} \qquad ( 8 )$$

where g is the non-dimensional gap between the structure and the stationary electrode, I̅ᵢ is the non-dimensional span of the electrode over ith beam, F₀ relates to static force, F₁ and F₂ relate to harmonic forces with frequencies Ω and 2Ω respectively.

Ideal clamp assumption at the two ends of the horizontal beam constrains the slope and displacement to be zero at S̅₁0 and S̅₂=0. Also, the displacement of the upper beam is measured from the coordinate at the beginning of the upper beam and as a result the displacement ν̅₃=0 at S̅₃=0. Apart from these five boundary conditions, the rest of the boundary conditions are as listed below:

$$\begin{matrix}\frac{\partial {\overline{v}}_{1}}{\partial {\overline{s}}_{1}} {\vert}_{{s}_{1} = 1} = \frac{{v}_{2}}{{v}_{1}} \frac{\partial {\overline{v}}_{2}}{\partial {\overline{s}}_{2}} {\vert}_{{s}_{2} = 1} , & ( 9 ) \\ {\overline{v}}_{1} {\vert}_{{\overline{s}}_{1} = 1} = - {\overline{v}}_{2} {\vert}_{{\overline{s}}_{2} = 1} , & ( 10 ) \\ \frac{\partial {\overline{v}}_{1}}{\partial {\overline{s}}_{1}} {\vert}_{{\overline{s}}_{1} = 1} = \frac{{v}_{3}}{{v}_{1}} \frac{\partial {\overline{v}}_{3}}{\partial {\overline{s}}_{3}} {\vert}_{{\overline{s}}_{3 = 0}} , & ( 11 ) \\ \begin{matrix}\frac{{α}_{1}}{{v}_{1}^{3}} \frac{{\partial }^{2} {\overline{v}}_{3}}{\partial {\overline{s}}_{2}^{2}} {\vert}_{{\overline{s}}_{1} = 1} - \frac{{α}_{2}}{{v}_{3}^{3}} \frac{{\partial }^{2} {\overline{v}}_{1}}{\partial {\overline{s}}_{1}^{2}} {\vert}_{{\overline{s}}_{1} = 1} = \\ ( ( 1 + {R}_{t} ) {r}_{3} {v}_{3} + {R}_{c} ( {r}_{1} {v}_{1} + {r}_{2} {v}_{2} ) ) {{v}^{\ddot{\_}}}_{1} {\vert}_{{s}_{1} = 1}\end{matrix} \} & ( 12 ) \\ \begin{matrix}\frac{{α}_{3}}{{v}_{3}^{2}} \frac{{\partial }^{2} {\overline{v}}_{3}}{\partial {\overline{s}}_{3}^{2}} {\vert}_{{\overline{s}}_{3} = 1} - \frac{{α}_{1}}{{v}_{1}^{2}} \frac{{\partial }^{2} {\overline{v}}_{1}}{\partial {\overline{s}}_{1}^{2}} {\vert}_{{\overline{s}}_{1} = 1} - \\ \frac{{α}_{2}}{{v}_{2}^{2}} \frac{{\partial }^{2} {\overline{v}}_{2}}{\partial {\overline{s}}_{2}^{2}} {\vert}_{{\overline{s}}_{2} = 1} = \frac{{γ}_{c}}{{v}_{1}} \frac{{\partial }^{3} {\overline{v}}_{1}}{\partial {τ}^{2} \partial {\overline{s}}_{1}} {\vert}_{{\overline{s}}_{1} = 1} ,\end{matrix} \} & ( 13 ) \\ \frac{{α}_{3}}{{v}_{3}} \frac{{\partial }^{2} {\overline{v}}_{3}}{\partial {\overline{s}}_{3}^{2}} {\vert}_{{\overline{s}}_{3} = 1} = {R}_{t} {r}_{3} {v}_{3} {\ddot{\overline{v}}}_{3} {\vert}_{{s}_{3} = 1} , & ( 14 ) \\ \frac{{α}_{3}}{{v}_{3}} \frac{{\partial }^{2} {\overline{v}}_{3}}{\partial {\overline{s}}_{3}^{2}} {\vert}_{{\overline{s}}_{3} = 1} = - {γ}_{t} \frac{{\partial }^{3} {\overline{v}}_{3}}{\partial {τ}^{2} \partial {\overline{s}}_{3}} {\vert}_{{\overline{s}}_{3} = 1} , & ( 15 )\end{matrix}$$

where non-dimensional parameters (Rₜ,γₜ) and (R_{c},γ_{c}), related to the rigid masses M_{c} and Mₜ respectively, as defined by:

$$\begin{matrix}{γ}_{t} = \frac{ {J}_{ t}}{ {ML}^{ 3}} , & {R}_{t} = \frac{{M}_{t}}{{m}_{3} {L}_{3}} , \\ {γ}_{c} = \frac{{J}_{c}}{{ML}^{3}} , & {R}_{c} = \frac{{M}_{c}}{( {m}_{1} {L}_{1} + {m}_{2} {L}_{2} )} .\end{matrix} \} \qquad ( 16 )$$

Boundary condition in equation (9) ensures that the slopes of the two horizontal beams 26, 28 are equal at the junction of these beams 26, 28. Equation (10) constrains the bottom two beams to have the same transverse displacement at the junction. The negative sign in this equation appears as the coordinate system for the left and right bottom beams are different. Equation (11) constrains the vertical beam 30 to be perpendicular to the horizontal beams 26, 28 at the junction thereof.

The boundary conditions in equations (12) and (15) can be derived by either doing the force and moment balance at the junction or by introducing the geometric boundary conditions in equations (9)-(11) as constraints in the Lagrangian using three more Lagrange multipliers and then eliminating Lagrange multipliers to determine the boundary conditions. The shear forces due to bending in the horizontal beams 26, 28 support the inertial force due to the displacement of the first mass 16, the second mass 18, and the vertical beam 30. This force balance at the junction results in the boundary conditions (12) and similarly the moment balance at the junction gives boundary condition in equation (13). The boundary conditions in equations (14) and (15) correspond to the force and moment balance at the tip of the vertical beam 30.

The linear mode shapes and natural frequencies are obtained by assuming the solution to have the following form:
ν̅ᵢ( s̅ᵢ,t)=Vᵢ( s̅ₜ)F(t), (17)
where Vᵢ is a spatial dependent function and F(t) is a harmonic function with frequency at ω. Substituting the assumed solution (17) into the governing equations (6), and separating space and time, we find that the following solution satisfies the governing equations:

$$\begin{matrix}{V}_{i} ( {\overline{s}}_{i} ) = {a}_{i} cos {β}_{i} {\overline{s}}_{i} + {b}_{i} sin {β}_{i} {\overline{s}}_{i} + \\ {c}_{i} cosh {β}_{i} {\overline{s}}_{i} + {d}_{i} sinh {β}_{i} {\overline{s}}_{i} ,\end{matrix} \} \qquad ( 18 )$$

where βᵢ is given by:

$${β}_{i}^{4} = \frac{{r}_{i} {v}_{i}^{4} {ω}^{2}}{{α}_{i}} . \qquad ( 19 )$$

The boundary conditions (at clamped ends and junction, and (9)-(15)) are used to now determine a characteristic matrix whose determinant is the characteristic equation. The roots of the characteristic equation determine natural frequencies (ω) and linear mode shapes are subsequently obtained for these natural frequencies by using the characteristic matrix. Thus, the exact linear mode shapes are obtained analytically.

The purpose of introducing first and second masses 16, 18 in the analysis is to make the model flexible enough to achieve desired design objectives. More specifically, as discussed above, to achieve 1:2 resonance without the additional masses 16, 18, the length ratios of the first and second components 12, 14 must be approximately 0.66 to 0.68. Once it is decided to keep the rigid masses or not, the linear analysis presented here can be used to identify conditions for which the structure exhibits 1:2 internal resonance and to obtain mode shapes and natural frequencies. The example used in this paper to illustrate the results of the analysis (linear and nonlinear) does not include any rigid mass; however, the formulation includes the rigid mass to keep the analysis presented here relevant to designs requiring the use of rigid masses. Another example discussed above for a 1:2 internal resonance between the two lowest modes of the microresonator is: the first mass 16 has a weight equal to the weight of the first component 12, the second mass 18 has a weight equal to the combined weight of the horizontal beams 26 and 28), the first component 12 has a length approximately equal to 108% (±2%) of one of the horizontal beams 26, 28.

Now, consider the specific system with no rigid masses and all three beams having the same mass per unit length and flexural rigidity. Also, we assume that the lengths of the horizontal beams are equal, L₁=L₂ or v₁=v₂. Thus, the only parameter that is not fixed is the ratio of the length of vertical beam to the length of one of the bottom beams (v₃/v₁). Natural frequency is computed analytically for different values of the length ratio (v₃/v₁). We found that when the ratio of the length of upper beam to the length of one of the bottom beams is 1.3266, the second natural frequency is twice that of the first natural frequency. This provides us with an important design condition to have 1:2 internal resonance. This critical ratio is denoted by

$${( \frac{{v}_{3}}{{v}_{1}} )}_{c} ,$$

with

$${( \frac{{v}_{3}}{{v}_{1}} )}_{c} = 1.3266 .$$

An ANSYS FEM model of T-beam structure is used to verify the above non-dimensional linear analysis. Beam elements are used in modeling the structure in ANSYS. As for the linear analysis, electrostatic actuation effects are considered of higher order, the FEM model also does not include electrostatic actuation. The dimensions of the structure with material properties of polysilicon are as follows:

$$\begin{matrix}{L}_{1} = 30 µm , & {L}_{3} = 30 \frac{{v}_{3}}{{v}_{1}} µm , \\ {E}_{1} = 150 \times {10}^{9} N \text{/} {m}^{2} , & {b}_{1} = 3 µm , \\ {I}_{1} = 0.84375 {( µm )}^{4} , & {m}_{1} = 0.010485 \frac{Kg}{( µm )} .\end{matrix} \} \qquad ( 20 )$$

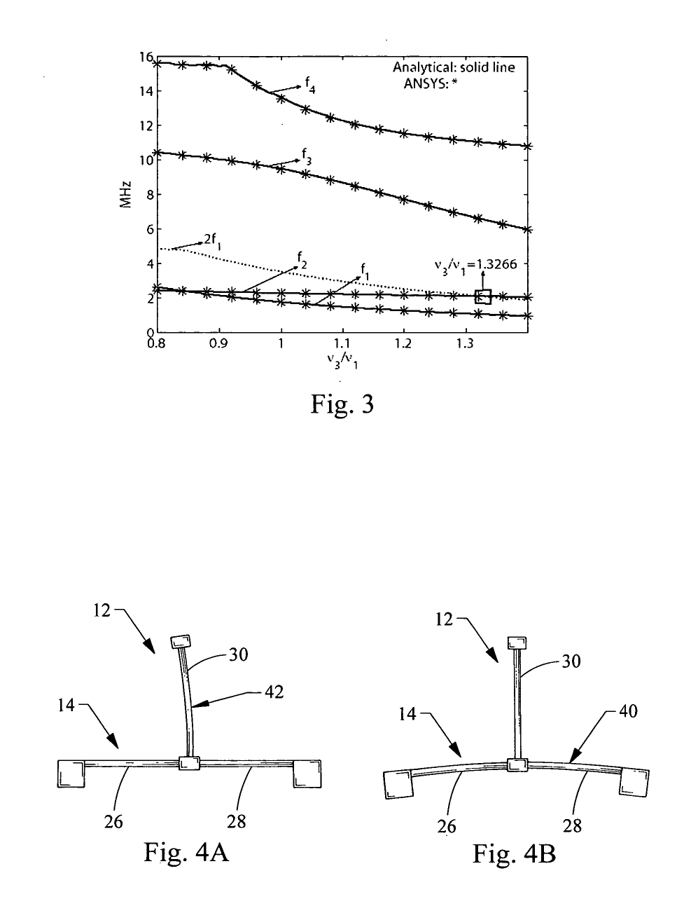

Also, all the beams have the same cross-sectional area and are made of the same material. The first four natural frequencies for this system for different values of the length ratio ν₃/ν₁ are shown in FIG. 3. The analytically computed mode shapes for the critical length

$${( \frac{{v}_{3}}{{v}_{1}} )}_{c} = 1.3266$$

are shown in FIG. 4. In the first (or the lower frequency) mode (mode 42), the horizontal beam moves very little as compared to the vertical beam. However, in the second mode (mode 40), the transverse displacement of the upper beam is zero. Due to the nature of the modes, note that the response in the second mode will not result in any deflection of vertical beam, unless energy is transferred from second mode to the first mode through 1:2 internal resonance. The nonlinear responses of the structure with 1:2 internal resonance between the first two modes are presented in the next section for two cases of resonant excitations: (a) the resonant excitation of the first mode, and (b) the resonant excitation of the second mode.
Nonlinear Response under Resonant Excitation

The electrostatic actuation terms are scaled such that they are of O(ε²) as follows:
Fⱼ=ε²\hat{F}ⱼ (21)
where j=0, 1, 2. This ordering ensures that the nonlinear terms in the Lagrangian and resonant excitation are at the same order in the analysis. The frequency of the first two modes of the structure are related to the actuation voltage frequency Ω as follows:
Ω=R₁ω₁(1+εσ₁), (22)
Ω=R₂ω₂(1+εσ₂), (23)
where ωᵢ is the ith natural frequency of the structure, σ₁ and σ₂ are the external detunings from perfect resonant excitation of either the first mode or the second mode. R₁ and R₂ determine the mode in primary resonance. Specifically, for R₁=1 and R₂=½, the first mode is in resonance and for R₁=2 and R₂=1, the second mode is in resonance. In using these tuning criteria we have assumed that the DC voltage, V_{b} is not zero. From equation (8), if the bias voltage is zero the actuation term with frequency Ω will be zero as well. In order to actuate the first (second) mode for the case of zero DC voltage, the frequency of the AC voltage should be tuned to half of the first (second) modes natural frequency. Since the AC signal for RF applications is very small, a DC voltage is used in most of the applications. Thus, there will be a higher harmonic at two times the natural frequency of the second mode. An ideal design will avoid any 1:2:4 resonance between the first three modes of the system so that the third mode is not excited from the higher harmonic present in the actuation.

FIG. 3 shows the first four natural frequencies,

$$fi = \frac{{ω}_{i}}{2 π} ,$$

of the T-beam structure as a function of the length ratio (L₃/L₁) or (v₃/v₁). The T-beam structure parameters are: no rigid masses (R_{c}=γ_{c}=Rₜ=γₜ₌0), equal mass per unit lengths (r₁=r₂=r₃), equal flexural rigidities (α₁=α₂=α₃), equal lengths of the horizontal beams (v₁=v₂). The solid line denotes analytically computed frequencies and the symbol “*” denotes frequencies computed using FEM ANSYS model of the structure. FIG. 4 shows the first two modes of the T-beam structure when the length ratio (L₃/L₁) or (v₃/v₁)=1.3266.

We can use the external detunings to relate the two natural frequencies up to O(ε) as follows:
ω₂=2ω₁(1+εσ_{I}) (24)
where
σ_{I}=σ₁−σ₂. (25)

Here, σ₁ is the internal mistuning between the first two natural frequencies from exact 1:2 resonance. The internal resonance between the two modes result in modal interaction between the first and second modes when either of the modes are directly excited by electrostatic actuation. Thus, there will be a nonzero response of both the first and second modes in steady state when either of the modes are excited directly. In comparison, the responses of other modes (which are not coupled by internal resonances) can be decaying due to damping in the structure. Thus, the displacements of the beam are approximated using the first two internally resonant modes, as follows:
v̅ᵢ=ε(A₁φ₁ᵢ+A₂φ₂ᵢ) (26)
u̅ᵢ=ε²(A₁²η₁₁ᵢ+A₂²η₂₂ᵢ+2A₁A₂η₁₂ᵢ) (27)
where Aᵢ are functions of time, φ₁ᵢ and φ₂ᵢ are the modal responses of the ith beam in first and second modes and are functions of the spatial coordinate s̅ᵢ. The variables ηⱼₖᵢ are also functions of the spatial coordinate s̅ᵢ. The eigenfunctions are determined by obtaining Vᵢ using equation (18) and the associated characteristic matrix for the linear system. The axial displacements are of order O(ε²) and are assumed to be caused by transverse displacements. This particular form of the axial displacement is motivated by the form of axial displacements in cantilever and clamped-clamped beam problems. The spatial form of the axial displacement of the ith beam is captured by ηⱼₖᵢ.

The spatial function for the vertical beam (beam 30) axial displacement, ηⱼₖ₃, is obtained by writing Lagrangian using the expressions in equation, retaining quadratic nonlinearities (terms up to O(ε³)), and then requiring L to be stationary with respect to the Lagrange multiplier λ₁. The spatial functions for beams 26 and 28 axial displacements, ηⱼₖ₁ and ηⱼₖ₂, are determined by including cubic nonlinearities (terms up to O(ε⁴)) in the Lagrangian and then neglecting inertia of the axial displacements. This process of neglecting inertia due to axial displacement is similar to the one used in the process of obtaining axial displacements in terms of, transverse displacement in clamped-clamped beam problem. Because the dynamics of the 1:2 internally resonant beam structure to the first order can be captured by retaining quadratic nonlinearities, the details of finding spatial functions are not provided here. The spatial functions obtained using the above approach are given by:

$$\begin{matrix}\begin{matrix}{η}_{jk 1} = - \frac{1}{2 {v}_{1}} [ {\int }_{0}^{{\overline{s}}_{1}} ( \frac{\partial {ϕ}_{j 1}}{\partial {\overline{s}}_{1}} ) ( \frac{\partial {ϕ}_{k 1}}{\partial {\overline{s}}_{1}} ) ⅆ {\overline{s}}_{1} - \\ \frac{{v}_{ 1}}{{v}_{1} + {v}_{2}} ( {\sum }_{i = 1}^{2} {\int }_{0}^{1} \frac{{v}_{1}}{{v}_{i}} ( \frac{\partial {ϕ}_{j i}}{\partial {\overline{s}}_{i}} ) ( \frac{\partial {ϕ}_{k i}}{\partial {\overline{s}}_{i}} ) ⅆ {\overline{s}}_{i} ) {\overline{s}}_{1} ]\end{matrix} \} & ( 28 ) \\ \begin{matrix}{η}_{jk 2} = - \frac{1}{2 {v}_{1}} [ \frac{{v}_{1}}{{v}_{2}} {\int }_{0}^{{\overline{s}}_{2}} ( \frac{\partial {ϕ}_{j 2}}{\partial {\overline{s}}_{2}} ) ( \frac{\partial {ϕ}_{k 2}}{\partial {\overline{s}}_{2}} ) ⅆ {\overline{s}}_{2} - \\ \frac{{v}_{ 2}}{{v}_{1} + {v}_{2}} ( {\sum }_{i = 1}^{2} {\int }_{0}^{1} \frac{{v}_{1}}{{v}_{i}} ( \frac{\partial {ϕ}_{j i}}{\partial {\overline{s}}_{i}} ) ( \frac{\partial {ϕ}_{k i}}{\partial {\overline{s}}_{i}} ) ⅆ {\overline{s}}_{i} ) {\overline{s}}_{2} ]\end{matrix} \} & ( 29 ) \\ {η}_{jk 3} = - \frac{1}{2 {v}_{3}} {\int }_{0}^{{\overline{s}}_{3}} ( \frac{\partial {ϕ}_{j 3}}{\partial {\overline{s}}_{3}} ) ( \frac{\partial {ϕ}_{k 3}}{\partial {\overline{s}}_{3}} ) ⅆ {\overline{s}}_{3} & ( 30 )\end{matrix}$$

where (j,k) can take values (1,1), (2,2) or (1,2).

Small changes in system parameters (like lengths of the beam segments, additional mass) can also mistune the system from perfect 1:2 internal resonance. To model this, we introduce mistunings in lengths from critical length ratios, and masses for 1:2 internal resonance. The mistunings are defined as follows:

$$\begin{matrix}\frac{{v}_{3}}{{v}_{1}} = {( \frac{{v}_{3}}{{v}_{1}} )}_{c} ( 1 + {ɛσ}_{L} ) , & {R}_{t} = {( {R}_{t} )}_{c} + ɛ {\hat{R}}_{t} , \\ {R}_{c} = {( {R}_{c} )}_{c} + ɛ {\hat{R}}_{c} , & {γ}_{t} = {( {γ}_{t} )}_{c} + ɛ {\hat{γ}}_{t} , \\ {γ}_{c} = {( {γ}_{c} )}_{c} + ɛ {\hat{γ}}_{c} . & \end{matrix} \} \qquad ( 31 )$$

The parameters denoted as ( )_{c}, represent design parameters for which the structure exhibits perfect 1:2 internal resonance. σ_{L} represents mistuning in the length ratio v₃/v₁, \hat{R}ₜ and \hat{R}_{c} represent mistunings in the tip mass and central mass respectively and j, and AC represent mistunings in the rotary inertias of the tip mass and central mass, respectively.

The weak nonlinear response of the structure is obtained by averaging the Lagangian over the time period Tp=4π/Ω of the primary oscillation or the fast time scale. The evolution of modal amplitudes and phases over slow time scale are determined using the averaged Lagrangian method. To explicitly introduce the slow time variables, the time dependent ith modal amplitude, Aᵢ, is assumed to be of the following form:

$${A}_{i} = {p}_{i} cos ( \frac{1}{{R}_{1}} i Ωτ ) + {q}_{i} sin ( \frac{1}{{R}_{1}} i Ωτ ) \qquad ( 32 )$$

where the pᵢ and qᵢ are quantities dependent on slow time scale T₁=ετ. The derivative of Aᵢ is as follows:

$$\begin{matrix}{\dot{A}}_{i} = \frac{1}{2} i Ω ( - {p}_{i} sin ( \frac{1}{2} i Ωτ ) + {q}_{i} cos ( \frac{1}{2} i Ωτ ) ) + \\ ɛ ( {p}_{i}^{′} cos ( \frac{1}{2} i Ωτ ) + {q}_{i}^{′} sin ( \frac{1}{2} i Ωτ ) )\end{matrix} \} \qquad ( 33 )$$

where a prime denotes derivative with respect to the slow time scale Tᵢ. Recall that a dot denotes derivative with respect to the fast time scale τ.

Using the above assumptions, and substituting the mistunings in equations (31), (22), and (23), displacements in equations (26) and (27), modal amplitudes in equation (32), and nondimensional parameters introduced in equations (7), (8), and (16) into the augmented Lagrangian, equation (5), and retaining terms up to O(ε³) results in the following:

$${L}_{aug} = ( \frac{EI}{L} ) ( ℒ + O ( {ɛ}^{4} ) ) . \qquad ( 34 )$$

The Lagrangian L depends only on non-dimensional parameters. Because the transverse displacements are measured from the static equilibrium, the electrostatic term with F₀, equation (8), will not appear in the Lagrangian. Also, given the way we have defined the axial displacement of beam 30, equation (30), the term with Lagrange multiplier λ₁ is zero. The averaged Lagrangian over the period Tp=4π/Ω is given by:

$$\begin{matrix}〈 ℒ 〉 = \frac{1}{{T}_{p}} {\int }_{0}^{{T}_{p}} ℒ ⅆ τ \\ = {ɛ}^{2} [ \frac{{r}_{1} {v}_{1}}{2} ( {\sum }_{j = 1}^{2} {Γ}_{j} {\vert}_{e = 0} \frac{1}{2} {( \frac{jΩ}{{R}_{1}} )}^{2} ( {p}_{j}^{2} + {q}_{j}^{2} ) ) - \\ \frac{{α}_{1}}{2 {v}_{1}^{3}} ( {\sum }_{j = 1}^{2} {Γ}_{2 + j} {\vert}_{ɛ = 0} \frac{1}{2} ( {p}_{j}^{2} + {q}_{j}^{2} ) ) + \\ ( {\overline{l}}_{1} + {\overline{l}}_{2} ) \frac{{\hat{F}}_{0}}{2} ] + \\ {ɛ}^{3} \frac{{r}_{1} {v}_{1}}{2} [ {\sum }_{j = 1}^{2} \frac{\partial {Γ}_{j}}{\partial ɛ} {\vert}_{ɛ = 0} \frac{1}{2} {( \frac{jΩ}{{R}_{1}} )}^{2} ( {p}_{j}^{2} + {q}_{j}^{2} ) - \\ ( {\sum }_{j = 1}^{2} {Γ}_{j} {\vert}_{ɛ = 0} \frac{jΩ}{{R}_{1}} ( {p}_{j} {q}_{j}^{′} - {q}_{j} {p}_{j}^{′} ) ) - \\ 2 ( {N}_{1} + {( {R}_{t} )}_{c} {N}_{2} ) {( \frac{Ω}{{R}_{1}} )}^{2} ( {p}_{1} {q}_{1} {q}_{2} + \\ \frac{1}{2} ( {p}_{1}^{2} - {q}_{1}^{2} ) {p}_{2} ) - \\ \frac{{α}_{1}}{{r}_{1} {v}_{1}^{4}} ( {\sum }_{j = 1}^{2} \frac{\partial {Γ}_{2 + j}}{\partial ɛ} {\vert}_{ɛ = 0} \frac{1}{2} ( {p}_{j}^{2} + {q}_{j}^{2} ) ) - \\ \frac{1}{2} \frac{{\hat{F}}_{1}}{g {r}_{1}} \{ ( {Γ}_{f 1} {p}_{1} {Δ}_{1} + {Γ}_{f 2} {p}_{2} {Δ}_{2} ) {M}_{2} + \\ ( {Γ}_{f 3} {p}_{1} {Δ}_{1} + {Γ}_{f 4} {p}_{2} {Δ}_{2} ) {M}_{1} \} ]\end{matrix} \} \qquad ( 35 )$$

where Γⱼ, N₁, N₂ and Γ_{fj}(j=1, 2, 3, 4) are defined in Appendix. Δ₁=1 when the first mode is in the primary resonance and zero when the second mode is in the primary resonance. Similarly, Δ₂=1 when the second mode is excited and zero when the first mode is excited. Although we only explicitly account for mistunings related to the parameters in equation (31), the Lagrangian formulated above can also account for mistunings in the variations in mass per unit lengths rᵢ, flexural rigidities αᵢ, and bottom beam length ratio v₂/v₁. These variations will also result in mistuning the first two modes of the structure away from 1:2 internal resonance. The terms up to O(ε²) represent linear terms and so the stiffness and inertia terms are related as follows:

$$\begin{matrix}\begin{matrix}\frac{{α}_{1}}{{r}_{1} {v}_{1}^{4}} {Γ}_{3} {\vert}_{ɛ = 0} = {ω}_{1}^{2} {Γ}_{1} {\vert}_{ɛ = 0} , \\ \frac{{α}_{1}}{{r}_{1} {v}_{1}^{4}} {Γ}_{4} {\vert}_{ɛ = 0} = {ω}_{2}^{2} {Γ}_{2} {\vert}_{ɛ = 0} .\end{matrix} \} & ( 36 )\end{matrix}$$

We substitute equation (36) and equations (22) and (23), in to equation (35) and then use the extended Hamilton's principle to derive Euler-Lagrange equations of motion. The resulting equations of motion, including the effect of the scaled modal damping (\hat{ξ}ᵢ) for ith modes are:

$$\begin{matrix}\begin{matrix}{p}_{1}^{′} = - {\overline{σ}}_{1} {ω}_{1} {q}_{1} - {\hat{ζ}}_{1} {ω}_{1} {p}_{1} + {ω}_{1} {Λ}_{1} ( {p}_{1} {q}_{2} - {q}_{1} {p}_{2} ) , \\ {q}_{1}^{′} = {\overline{σ}}_{1} {ω}_{1} {p}_{1} - {\hat{ζ}}_{1} {ω}_{1} {q}_{1} - {ω}_{1} {Λ}_{1} ( {p}_{1} {p}_{2} + {q}_{1} {q}_{2} ) - {E}_{1} , \\ {p}_{2}^{′} = - {\overline{σ}}_{2} {ω}_{2} {q}_{2} - {\hat{ζ}}_{2} {ω}_{2} {p}_{2} + 2 {ω}_{1} {Λ}_{2} {p}_{1} {q}_{1} , \\ {q}_{2}^{′} = {\overline{σ}}_{2} {ω}_{2} {p}_{2} - {\hat{ζ}}_{2} {ω}_{2} {q}_{2} - {ω}_{1} {Λ}_{2} ( {p}_{1}^{2} - {q}_{1}^{2} ) - {E}_{2} ,\end{matrix} \} \\ where & ( 37 ) \\ \begin{matrix}{\overline{σ}}_{j} = {σ}_{j} + \frac{1}{2 {ω}_{j}^{2} {Γ}_{j} {\vert}_{ɛ = 0}} & \\ [ \begin{matrix}( {ω}_{j}^{2} {S}_{1 j} - \frac{{α}_{1}}{{r}_{1} {v}_{1}^{4}} {S}_{2 j} ) {σ}_{L} + {ω}_{j}^{2} \\ ( \begin{matrix}{S}_{3 j} {\hat{R}}_{t} + {S}_{4 j} {\hat{R}}_{c} + \\ {S}_{5 j} {\hat{γ}}_{t} + {S}_{6 j} {\hat{γ}}_{c}\end{matrix} )\end{matrix} ] , & \\ {E}_{1} = \frac{1}{4} \frac{{\hat{F}}_{1}}{g {r}_{1} {ω}_{1} {Γ}_{1} {\vert}_{ɛ = 0}} ( {Γ}_{f 1} {M}_{2} + {Γ}_{f 3} {M}_{1} ) {Δ}_{1} , & \\ {E}_{2} = \frac{1}{4} \frac{{\hat{F}}_{1}}{g {r}_{1} {ω}_{2} {Γ}_{2} {\vert}_{ɛ = 0}} ( {Γ}_{f 2} {M}_{2} + {Γ}_{f 4} {M}_{1} ) {Δ}_{2} , & \\ {Λ}_{1} = \frac{( {N}_{1} + {( {R}_{t} )}_{c} ( {N}_{2} )}{{Γ}_{1} {\vert}_{ɛ = 0}} , & {Λ}_{2} = \frac{( {N}_{1} + {( {R}_{t} )}_{c} {N}_{2} )}{4 {Γ}_{2} {\vert}_{ɛ = 0}} , \\ {S}_{1 j} = \frac{{\partial }^{2} {Γ}_{j}}{\partial ɛ \partial {σ}_{L}} {\vert}_{ɛ = 0} , & {S}_{2 j} = \frac{{\partial }^{2} {Γ}_{2 + j}}{\partial ɛ \partial {σ}_{L}} {\vert}_{ɛ = 0} , \\ {S}_{3 j} = \frac{{\partial }^{2} {Γ}_{j}}{\partial ɛ \partial {R}_{t}} {\vert}_{ɛ = 0} , & {S}_{4 j} = \frac{{\partial }^{2} {Γ}_{j}}{\partial ɛ \partial {R}_{c}} {\vert}_{ɛ = 0} , \\ {S}_{5 j} = \frac{{\partial }^{2} {Γ}_{j}}{\partial ɛ \partial {\hat{γ}}_{t}} {\vert}_{ɛ = 0} , & {S}_{6 j} = \frac{{\partial }^{2} {Γ}_{j}}{\partial ɛ \partial {\hat{γ}}_{c}} {\vert}_{ɛ = 0} .\end{matrix} \} & ( 38 )\end{matrix}$$

The actual modal damping, ξᵢ, of the ith mode is related to the scaled damping, (\hat{ξ}ᵢ), as follows:
ζₜ=ε\hat{ζ}ᵢ. (39)
The \hat{σ}ᵢ in averaged equations (37) represents the effective external mistuning of the ith mode. This effective mistuning includes the sensitivities Sⱼᵢ of different structure parameters as given in the equation (38). An effective internal mistuning of the two modes from 1:2 internal resonance, σ̅ᵢ, can thus be written as follows:
σ̅_{I}= σ̅₁− σ̅₂. (40)

The averaged equations (37) obtained here are identical to the averaged equations obtained for quadratically coupled internally resonant oscillators when excited externally in the first or second mode. These quadratically coupled oscillators are studied by many researchers for equilibrium solutions and bifurcations re suiting in complex dynamics.

Response of an Illustrative Structure

Consider the T-shaped structure discussed while illustrating the results of linear analysis. The specific nominal T-beam structure had no rigid masses, and all the three beam segments have the same mass per unit lengths and the same flexural rigidities for all the beams. Further, the lengths and widths of the two bottom beams are equal. We choose nominal parameters as the parameters of the bottom left beam, the beam 26. These assumptions are written in terms of parameter values defined in the equations (7) and (16), as follows:

$$\begin{matrix}{r}_{j} = 1 , & {α}_{j} = 1 , & {v}_{1} = 1 , & {v}_{2} = 1 , \\ {( {R}_{c} )}_{c} = 0 , & {( {R}_{t} )}_{c} = 0 , & {( {γ}_{c} )}_{c} = 0 , & {( {γ}_{t} )}_{c} = 0 , \\ {v}_{3} {\vert}_{c} = 1.3266 , & & & \end{matrix} \} \qquad ( 41 )$$

where j=1, 2, 3. The non-dimensional natural frequencies of the system obtained by linear analysis are as follows:
ω₁=1.699, ω₂=3.398. (42)
The first two mode shapes are computed analytically and the mode shapes are normalized to have Γ_{1|E=0}=Γ_{2|ε=0}=1.

The microresonator structure's actual dimension are assumed to be the same as specified in equation (20). The gap between the horizontal beams 26, 28 and the second electrode 20 is fixed at d=1 μm. The gap between the vertical beam 30 and the first electrode 24 is also fixed at d₃=1 μm. All these dimensions are chosen keeping in mind the fabrication constraints. Using the permittivity of air and the mode shapes, the different terms defining forcing term reduces to just a function of applied voltage, as given below:

$$\begin{matrix}( \frac{1}{4} \frac{{\hat{F}}_{1}}{g {r}_{1}} ) = \frac{2.83 {TV}_{b} V}{{ɛ}^{3}} \times {10}^{- 6} , \\ {Γ}_{f 1} = {Γ}_{f 4} = 0 , \\ {Γ}_{f 2} = 0.421 , \\ {Γ}_{f 3} = 0.868\end{matrix} \} \qquad ( 43 )$$

The parameters in the above equation (43) suggest that, to the first order approximation, the first mode cannot be excited directly by using the second electrode 20, and similarly the second mode cannot be directly excited by the first electrode 24. This filtering of the first mode frequency when actuating by the second electrode 20 (and second mode frequency when actuating by the first electrode 24) is due to the mode shape of the system. This filtering characteristic will also be valid in general for microresonator structures as long as the symmetry of the structure is maintained.

The other parameters required to compute all the coefficients in the averaged equations (37) for this system are as follows:

$$\begin{matrix}{S}_{11} = 0.998 , & {S}_{21} = 33.989 , & {S}_{31} = 3.714 , \\ {S}_{41} = 0 , & {S}_{51} = 2.602 , & {S}_{61} = 0.101 , \\ {S}_{12} = 0.6357 , & {S}_{22} = 0 , & {S}_{32} = 0.636 , \\ {S}_{42} = 0.958 , & {S}_{52} = 0 , & {S}_{62} = 0 \\ {Λ}_{1} = 0.7634 , & {Λ}_{2} = 0.1908 . & \end{matrix} \} \qquad ( 44 )$$

The parameters Sᵢⱼ determine the sensitivity of jth natural frequency to changes in different parameters, see Equation (38). The values of S₁₁ and S₂₁ suggest that the first mode is very sensitive to any changes in the length ratio (v₃/v₁). However, attaching a central rigid mass, parameter S₄₁, does not affect the natural frequency of the first mode. The parameters S₅₂ and S₆₂ suggest that the rotational inertia of the rigid masses do not affect the second mode natural frequency. Λ₁ and Λ₂ represent the strength of nonlinear coupling between the two modes.

The quality factor Q (as traditionally defined for liner systems) for the response of a microresonator in ith mode is (1/2ζᵢ), where (ζi is the modal damping for ith mode. Since, quality factor is an important performance parameter for a microresonator, we compute the response of this structure for different values of damping coefficients. The structure is assumed to have perfect internal resonance, σ̅₁=0, and the effects of different parameter sensitivities on the response are not discussed here. For a given excitation voltage and excitation in either mode, the decrease in damping of the first and second mode can result in Hopf bifurcations and thereby period doubling bifurcations and chaotic motions of the beam. The internal mistuning of the first two modes from 1:2 internal resonance also plays a critical role in determining the existence of Hopf bifurcation in the system dynamics. If the two modes are in perfect internal resonance, the system will not have any Hopf bifurcation when the second mode is excited directly. However, when the first mode is excited directly (Δ₁=1); the system with the two modes in perfect internal resonance can still undergo Hopf bifurcation.

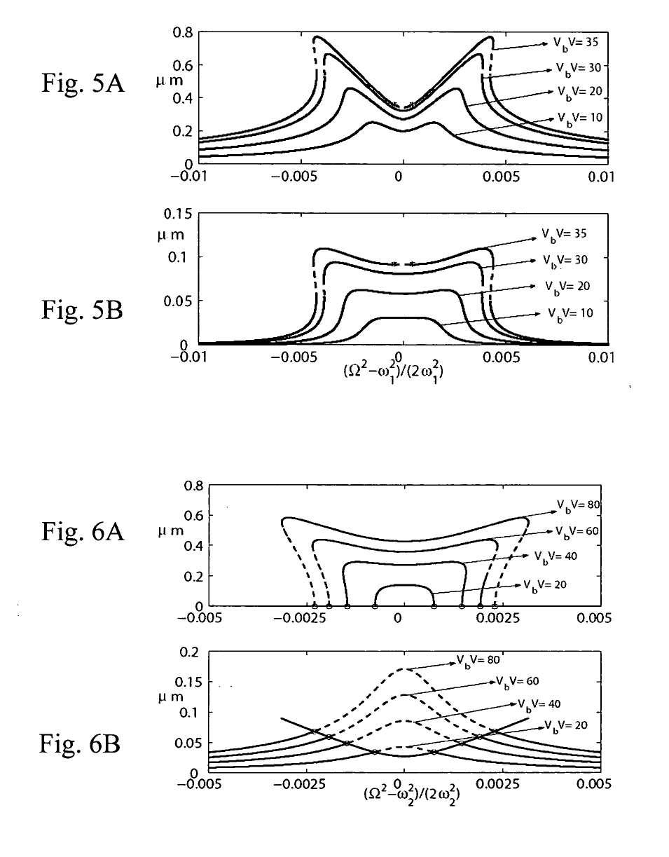

The response of the structure is simulated in bifurcation and continuation software AUTO with scaling parameter ε=0.01 to scale the response to O(l). First, we consider a structure with low quality factor Q=500 for both the modes, and thus fix the value of damping parameters, ζ₁ and ζ₂, to 0.001. The scaled modal damping is then obtained using equation (39). The response obtained using AUTO is then scaled back to the actual beam displacements using equations (7), (16), and (27). When the structure is excited directly in the first mode, the structure is actuated using the first electrode 24. For the direct excitation of the second mode, the second electrode 20 is used for actuation. FIG. 5 shows the response for the primary resonance of the first mode in terms of the displacements at the tip of the upper beam for first mode (FIG. 5(a)) and at the junction of the three beams for second mode (FIG. 5(b)) for different input voltages. The modal response thus plotted is the maximum displacement of the structure in that particular mode. The response undergoes Hopf-bifurcation for higher voltages. When the first mode is directly excited, the response in both the modes remains non-zero over the entire bandwidth of interest. The sensor output signal at the second electrode 20 is at double the input frequency and also act as a mixer (upconversion) and filter for the input signal.

Similarly, FIG. 6 shows the response for the primary resonance of second mode. While FIG. 6(a) shows the transverse (horizontal) displacement of the tip of the upper beam 30, FIG. 6(b) shows the response of the junction of the three beams 26, 28 and 30. Interestingly, when the second mode is excited, the response of the first mode, and hence the tip of the upper beam 30, is non-zero only for a certain range of frequency, and thus the response in first mode per forms a filtering action on the input signal. Further, in this case the first electrode 24 output signal is at half the input frequency and thus the resonator acts as a mixer (downconversion).

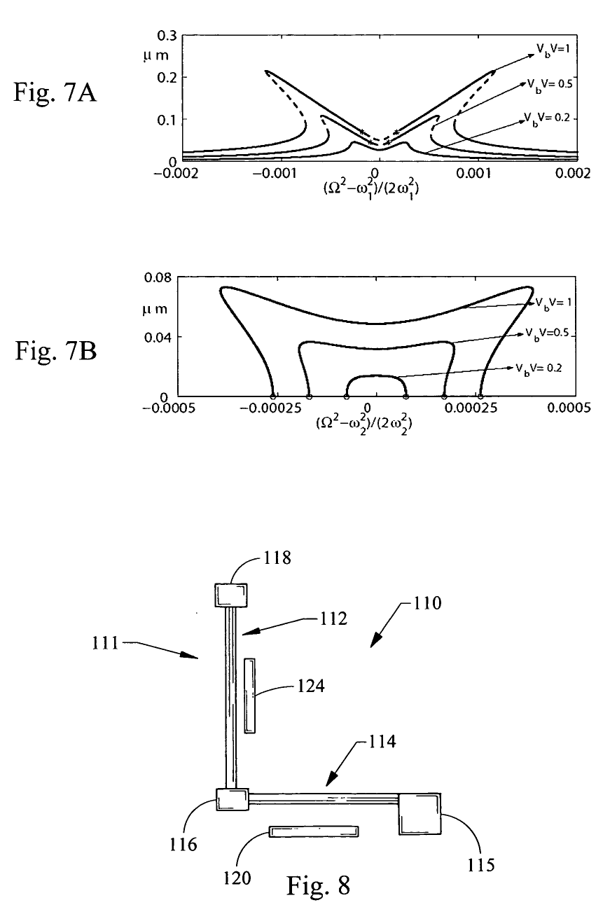

FIG. 7 depict the horizontal displacement of the tip of the upper beam 30. FIG. 7(a) shows the response in the first mode when the first mode is excited directly for a structure having a higher quality factor Q=5000 (achievable easily for micro resonators in vacuum, may be difficult in air). The response again undergoes Hopf bifurcation for higher voltages. The appearance of Hopf bifurcation depends on the strength of excitation in comparison to the structure damping. FIG. 7(b) shows the response in the first mode for the same structure when the second mode is in primary resonance, that is the structure is excited by the electrode 20. Since the two modes of the microresonator structure are assumed to be in perfect internal resonance, there is no Hopf bifurcation in the response of the system in FIG. 7(b). Further, the response changes appreciably with voltage when either of the modes are excited. This may limit the power handling capacity of such resonators.

The Γⱼ and other undefined variables in Lagrangian are defined below. These variables are constant with respect to time and are determined by the mode shapes of the structure.

$$\begin{matrix}\begin{matrix}{Γ}_{j} = ( {\sum }_{i = 1}^{3} {\int }_{0}^{1} \frac{{r}_{i} {v}_{i}}{{r}_{1} {v}_{1}} {ϕ}_{ji}^{2} ⅆ {\overline{s}}_{i} ) + ( \frac{{r}_{3} {v}_{3}}{{r}_{1} {v}_{1}} ( 1 + {R}_{t} ) + \\ {R}_{c} ( 1 + \frac{{r}_{2} {v}_{2}}{{r}_{1} {v}_{1}} ) ) {ϕ}_{j 1}^{2} {\vert}_{{\overline{s}}_{1} = 1} + \\ \frac{{γ}_{c}}{{r}_{1} {v}_{1}^{3}} {( \frac{\partial {ϕ}_{j 1}}{\partial {\overline{s}}_{1}} )}^{2} {\vert}_{{\overline{s}}_{1} = 1} + {R}_{t} \frac{{r}_{3} {v}_{3}}{{r}_{1} {v}_{1}} {ϕ}_{j 3}^{2} {\vert}_{{\overline{s}}_{3} = 1} + \\ \frac{{γ}_{t}}{{r}_{1} {v}_{1}^{3}} {( \frac{{v}_{1}}{{v}_{3}} )}^{2} {( \frac{\partial {ϕ}_{j 3}}{\partial {\overline{s}}_{3}} )}^{2} {\vert}_{{\overline{s}}_{3} = 1}\end{matrix} \} & ( 45 ) \\ {Γ}_{2 + j} = {\sum }_{i = 1}^{3} {\int }_{0}^{1} \frac{{α}_{i} {v}_{1}^{3}}{{v}_{i}^{3} {α}_{1}} {( \frac{{\partial }^{2} {ϕ}_{ji}}{\partial {\overline{s}}_{i}^{2}} )}^{2} ⅆ {\overline{s}}_{i} & ( 46 )\end{matrix}$$

where j=1 and 2. The Γⱼ and Γ₂₊ⱼ are dependent on the parameter ε as the terms appearing in the above equations like v₃/v₁, Rₜ, R_{c} are dependent on the ε as defined by the equations (31).

The other three terms N₁, N₂ and Γ_{f} are also dependent on the mode shapes. These terms are as follows:

$$\begin{matrix}{N}_{1} = {\int }_{0}^{1} I ⅆ {\overline{s}}_{3} & ( 47 ) \\ {N}_{2} = I {\vert}_{{\overline{s}}_{3} = 1} & ( 48 ) \\ {Γ}_{fj} = {\int }_{1 - {\overline{l}}_{1}}^{1} {ϕ}_{j 1} ⅆ {\overline{s}}_{1} + \frac{{b}_{2} {v}_{2}}{{b}_{1} {v}_{1}} \begin{matrix}{\int }_{1 - {\overline{l}}_{2}}^{1} {ϕ}_{j 2} ⅆ {\overline{s}}_{2} , & j = 1 , 2 ,\end{matrix} & ( 49 ) \\ \begin{matrix}{Γ}_{fk} = \frac{ⅆ {b}_{3} {v}_{3}}{{ⅆ}_{3} {b}_{1} {v}_{1}} {\vert}_{ɛ = 0} {\int }_{1 - {\overline{l}}_{3}}^{1} {ϕ}_{k 3} ⅆ {\overline{s}}_{3} , & k = 3 , 4 ,\end{matrix} \\ where \\ j = 1 , 2 , \\ and & ( 50 ) \\ \begin{matrix}I = \{ 2 \frac{{r}_{3}}{{r}_{1}} \frac{{v}_{3}}{{v}_{1}} [ ( {η}_{111} {\vert}_{{\overline{s}}_{1} = 1} {ϕ}_{23} - {η}_{121} {\vert}_{{\overline{s}}_{1} = 1} {ϕ}_{13} ) - \\ ( {ϕ}_{21} {\vert}_{{\overline{s}}_{1} = 1} {η}_{113} - {ϕ}_{11} {\vert}_{{\overline{s}}_{1} = 1} {η}_{123} ) ] \} {\vert}_{ɛ = 0}\end{matrix} \} & ( 51 )\end{matrix}$$

Referring now to FIG. 8, a second embodiment of the present invention is shown. The micromechanical resonator 110 includes a structure 111 having a first component 112 and a second component 114 generally defining an L-shaped configuration, where the second component 114 is connected to substrate 15. The resonator 110 further includes a first mass 116 connected to both components 112, 114, a second mass 118 connected to the free end of the first component 112, a first electrode 124 positioned adjacent to the first component 112, and a second electrode positioned adjacent to the second component 114. As with the resonator described above, the resonator embodies two modes, a lower natural frequency mode (the first mode) and a higher frequency mode (the second mode). The second mode, which may be induced by the second electrode 120, is embodied by both the first and second components 112, 114. Specifically, the second mode includes pivoting movement of the structure 111 about a point near the base 115. Additionally, the first mode, which also includes pivoting movement about the substrate 115, is embodied by both the first component 112 and the second component 114. As with the resonator 10 described above, the first mode is induced by the second mode through non-linear modal interaction. Due to the unsymmetrical nature of the structure 111, the first component 112 will move or flex parallel to the horizontal axis when the second component is deflecting or flexing along the vertical direction.

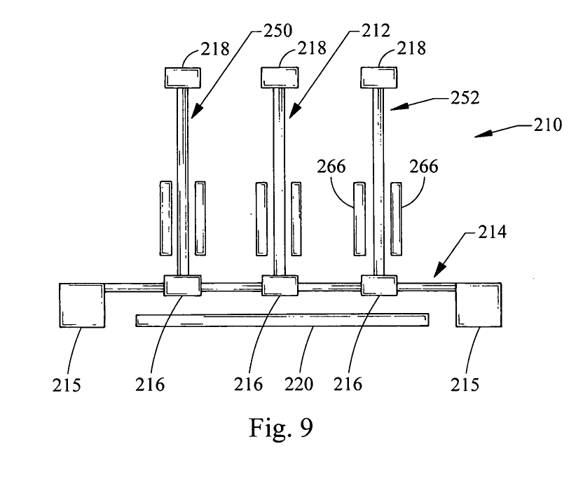

Referring now to FIG. 9, a third embodiment of the present invention is shown. The micromechanical resonator 210 includes a structure 111 having a second component 214 extending between two points on a base or substrate 215 and a first component 214, a third component 250 and a fourth component 252, each extending generally vertically from the second component such that the structure 111 generally defines an comb-shaped configuration. The resonator 110 further includes a plurality of first masses 116 connected to intersection points between the second component 214 and the perpendicular components 212, 250, 252. Additionally, the first component 214 includes an electrode 220 positioned adjacent thereto and each of the perpendicular components 212, 250, 252 includes a pair of electrodes 266 positioned on opposite sides thereof. The resonator 210 embodies a second mode including movement generally along the vertical axis and a first mode including movement generally along the horizontal axis. As with the resonator 10 described above, one of the modes may be induced by the electrode 220 or the pairs of electrodes 266 and the other mode is induced by non-linear internal resonance between the two modes. Also similarly to the resonator 10 described above, the first mode is linearly decoupled from the second mode when the second component 214 is vibrating at a frequency twice the natural frequency of the first mode.

It is therefore intended that the foregoing detailed description be regarded as illustrative rather than limiting, and that it be understood that it is the following claims, including all equivalents, that are intended to define the spirit and scope of this invention.

1. A micromechanical resonator comprising a structure configured to define a first mode and a second mode and to permit non-linear internal resonance between the first and second modes.

2. A micromechanical resonator as in claim 1, the structure configured to permit 1:2 non-linear internal resonance between the second mode and the first mode.

3. A micromechanical resonator as in claim 1, further comprising an actuator configured to resonate the structure and induce the second mode.

4. A micromechanical resonator as in claim 1, the second mode embodied by at least a second component extending along a second direction and the first mode embodied by at least a first component extending along a first direction.

5. A micromechanical resonator as in claim 4, the first direction generally perpendicular to the second direction.

6. A micromechanical resonator as in claim 5, the first and second components generally defining a T-shaped configuration.

7. A micromechanical resonator as in claim 6, the second component having a first beam and a second beam each defining a beam length, and the first component having a first component length equal to approximately 133% of the beam length of at least one of the first and second beams.

8. A micromechanical resonator as in claim 4, further comprising a mass coupled with at least one of the first and second components.

9. A micromechanical resonator as in claim 8, the mass positioned adjacent to an intersection point between the first component and the second component.

10. A micromechanical resonator as in claim 9, further comprising a second mass positioned adjacent to a second end of the first component.

11. A micromechanical resonator as in claim 4, the first component defining at least one first natural resonance frequency and the second component defining at least one second natural resonance frequency, the first and second modes substantially completely non-linearly coupled with each other while the second component vibrates at a frequency approximately twice the at least one first natural resonance frequency.

12. A micromechanical resonator as in claim 5, the first and second components generally defining an L-shaped configuration.

13. A micromechanical resonator as in claim 5, further comprising a third component and a fourth component each extending generally parallel to the first component.

14. A micromechanical resonator comprising a structure having a first component embodying a first mode and a second component embodying a second mode, the first component defining at least one first natural resonance frequency and the second component defining at least one second natural resonance frequency, the first and second modes substantially completely non-linearly coupled with each other while the second component vibrates at a frequency approximately twice the at least one first natural resonance frequency.

15. A micromechanical resonator as in claim 14, the first and second components generally defining a T-shaped configuration.

16. A micromechanical resonator as in claim 14, further comprising a third component and a fourth component each extending generally parallel to the first component.

17. A micromechanical resonator as in claim 14, the first frequency is approximately one half of the second frequency.

18. A micromechanical resonator comprising:
a structure having a first component and a second component; and
an actuator configured to induce resonant excitation of the second component at a second frequency;
wherein the second component is positioned with respect to the first component such that the resonant excitation of the second component at the second frequency induces resonant excitation of the first component at a first frequency.

19. A micromechanical resonator as in claim 15, the first frequency is approximately one half of the second frequency.

20. A micromechanical resonator as in claim 18, the first and second components generally defining a T-shaped configuration.

21. A micromechanical resonator as in claim 18, the first and second components generally defining an L-shaped configuration.

22. A micromechanical resonator as in claim 18, further comprising a third component and a fourth component each extending generally parallel to the first component.
